(19) United States
(12) Patent Application Publication
(10) Pub. No.: US 2010/0126942 A1
(43) Pub. Date: May 27, 2010

(54) MULTI-FREQUENCY ULTRASONIC APPARATUS AND PROCESS WITH EXPOSED TRANSMITTING HEAD

(76) Inventors: Sebastian K. Thottathil, Robbinsville, NJ (US); J. Michael Goodson, Skillman, NJ (US)

Correspondence Address: K&L Gates LLP;IP Docketing, 630 Hansen Way, Palo Alto, CA, 94304, US

(21) Appl. No.: 12/623,271

(22) Filed: Nov. 20, 2009

Related U.S. Application Data
(60) Provisional application No. 61/116,315, filed on Nov. 20, 2008.

(51) Int. Cl. H01L 41/09; B06B 1/06; H01L 41/053; C02F 1/36

(52) U.S. Cl. 210/748.03; 310/322; 310/344; 310/342; 310/317; 210/205

(57) ABSTRACT

The present invention is an ultrasonic device with the transmitting head located outside a housing enclosure while radial mode PZTs and tail mass are located inside the housing enclosure. The ultrasonic device and related process are useful for any process involving supplying ultrasonic energy to a liquid, including controlling algae and decontaminating liquids with multiple ultrasonic transmitters driven at variable frequencies. A broad range of algae can be successfully controlled and various liquids can be decontaminated or otherwise processed in a rapid and effective way. Each transmitter is housed in an enclosure that can float on the surface of tanks; pools, reservoirs, lakes, ponds, and water and waste-water facilities. Alternatively, the transmitters can be attached to a structure and positioned with the transmitting head immersed into the liquid. The exposed transmitting head efficiently transmits ultrasonic energy to the liquid.

### RELATED APPLICATION

This application claims priority from co-pending U.S. Provisional Application No. 61/116,315, filed Nov. 20, 2008, entitled FREQUENCY SWEEP AND MULTIFREQUENCY ULTRASONIC TRANSMITTING DEVICE TO CONTROL ALGAE AND VARIOUS TYPE OF CONTAMINATION IN A LIQUID, and invented by Sebastian K. Thottathil and J. Michael Goodson. This prior application is expressly incorporated herein by reference.

### BACKGROUND OF THE INVENTION

### 1. Field of the Invention

This invention relates generally to ultrasonic apparatus and associated process methods for improving transmission of radial mode ultrasonic vibrations into liquids, and relates more specifically to an ultrasonic device with an exposed transmitting head and associated process for controlling algae, decontaminating liquids, and other applications.

2. Description of the Relevant Art

Algae is found through out the world and is a general nuisance in water treatment plants, drinking water supplies, irrigation reservoirs, fish ponds, water impoundments, swimming pools, cooling towers, and underwater surfaces of ships and boats. Algae can be physically removed by using raking or other devices, but this is very labor intensive and only a temporary control. Some algae types can grow as fast as they can be removed. Algae can also be treated chemically, but at the risk of potential contamination of the water and harm to the water stock.

Another way to remove algae is to use ultrasonic vibrations to break down the outer membranes of the algae. This method is environmentally friendly, cost effective, and chemical free. However, killing the various types of algae has not been successful using single frequency ultrasonic device. Some types of algae required low frequency ultrasonic energy to kill them and other types of algae can not be killed by low frequencies. Also low frequency devices do not have uniform coverage because of its large wave length. What is needed is a more powerful and efficient ultrasonic process for removing algae.

More generally, what is needed is a way to improve the transmission of ultrasonic energy into a liquid for a range of applications beyond killing algae, and including precision cleaning and liquid processing using ultrasonics. Prior ultrasonic devices typically are a stacked construction with one or more piezoelectric (PZT) devices sandwiched between a head mass and a tail mass and held together with a compression bolt. Such devices are typically attached to the outside of a tank or other container by bonding or welding the head mass to the structure of the tank or container. Alternatively, the ultrasonic device may be attached inside a sealed box that is immersed into the tank or container. These devices transmit ultrasonic energy from the PZT through the head mass and the structure of the tank, container, or immersible box.

### SUMMARY OF THE INVENTION

The present invention is an ultrasonic device and related process having a transmitting head mass of one or more radial-mode ultrasonic transducers in direct contact with the liquid, with the remainder of the transducer enclosed in a watertight housing. The head mass of the transducer transmits ultrasonic energy directly to the liquid instead of an intermediate structure. An ultrasonic generator drives the one or more ultrasonic transducers at variable frequencies to maximize efficient transmission of ultrasonic energy.

The present invention is useful for controlling algae, decontaminating liquids, and other ultrasonic processing in liquids with multiple ultrasonic transmitters driven by a driving signal that continuously varies in frequency. The direction and orientation of each transmitter is horizontally freely adjustable in order to accommodate many treatment layouts. The multiple transmitters result in frequency super-positioning and interference between the different ultrasonic waves that are emitted by the transmitters of different orientation and different distances to the point of interference. The combination of multi-directional ultrasonic waves and continuous frequency sweeping around a center frequency enhances the interferences, resulting in a strong dB gain of the signals at any point within the reach of the transmitters.

By using both low frequency and high frequency ultrasonic transducers with both transducers connected to a frequency sweeping generator, the low and high frequency waves interact. Because of the interaction, peaks and valleys of the waves will be close to each other provide uniform coverage. The high frequencies lose amplitude more quickly than lower frequencies. By combining the two, the low frequency wave can carry the high frequency wave further away for large area coverage.

As a result, a broad range of algae can be successfully controlled and various liquids can be decontaminated or otherwise processed in a rapid and effective way. Amplitude controls on the generator allow the adjustment of the power setting to optimize for various types of algae infestations or contaminants, and to economize energy for the maintenance period following the successful control of the initial algae burden.

The transmitters are housed in a unit that can float on the surface of pools, reservoirs, lakes, fish and farm ponds and water and waste water management facilities. Alternatively, the transmitters can be attached to a structure and positioned with the exposed transmitting head mass immersed in the liquid. The multi-frequency ultrasonic waves disrupt and destroy the cellular structure and function of algae, and also break down contaminants in liquids. The present invention further includes an associated method of transmitting ultrasonic waves under water to control a broad range of algae species and/or break down a broad range of contaminants. More generally, the exposed transmitting head masses of the transducers can be used in any application where radial mode ultrasonic energy is supplied to a liquid.

The features and advantages described in the specification are not all inclusive, and particularly, many additional features and advantages will be apparent to one of ordinary skill in the art in view of the drawings, specification and claims hereof. Moreover, it should be noted that the language used in the specification has been principally selected for readability and instructional purposes, and may not have been selected to delineate or circumscribe the inventive subject matter, resort to the claims being necessary to determine such inventive subject matter.

### BRIEF DESCRIPTION OF THE DRAWINGS

FIG. 1 is a schematic view of one embodiment of a multi-frequency ultrasonic apparatus according to the present invention.

FIG. 2 is a perspective view of one embodiment of a multi-frequency ultrasonic apparatus according to the present invention.

FIG. 3 is a side view, partially cut away, of the apparatus of FIG. 2.

FIG. 4 is a perspective view of another embodiment of a multi-frequency ultrasonic apparatus according to the present invention with multiple transmitters.

FIG. 5 is a side sectional view of another embodiment of a multi-frequency ultrasonic apparatus according to the present invention.

FIG. 6 is a schematic view of another embodiment of a multi-frequency ultrasonic apparatus according to the present invention with multiple transducers.

FIG. 7 is a schematic view of one embodiment of a multi-frequency ultrasonic apparatus according to the present invention with multiple transducers of different dimensions and operating frequencies.

FIG. 8 is a side view of an embodiment of the present invention with probes for increasing the surface area of the transmitting unit.

FIG. 9 is a side view of another embodiment of the present invention with multiple transmitting units attached to a pipe line.

### DETAILED DESCRIPTION OF THE PREFERRED EMBODIMENTS

The drawings depict various preferred embodiments of the present invention for purposes of illustration only. One skilled in the art will readily recognize from the following discussion that alternative embodiments of the structures and methods illustrated herein may be employed without departing from the principles of the invention described herein.

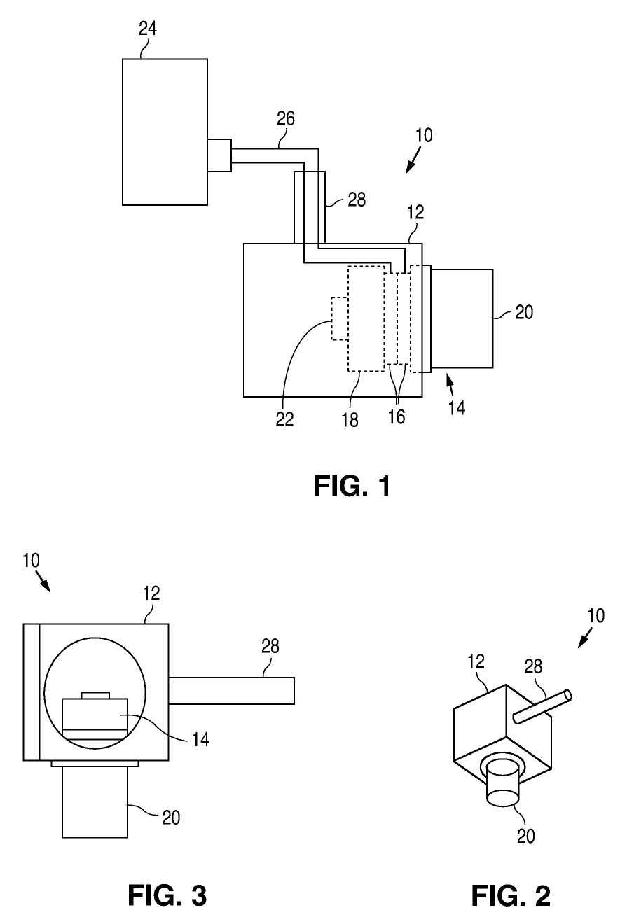

As shown in FIGS. 1-3, the ultrasonic device 10 has a unibody design that integrates the housing 12 of the device with the ultrasonic transducer 14. The transducer 14 includes ring-shaped piezoelectric (PZT) elements 16, a tail mass 18 on one side of the PZTs, and a transmitting head 20 (also known as a head mass or transmitting head mass) on the other side of the PZTs. The assembly is held together with a compression bolt 22. The PZT elements 16 are preferably radial mode devices. An ultrasonic generator 24 supplies a driving signal to the PZTs through a signal cable 26. The frequency of the driving signal is preferably swept or otherwise varied by the generator throughout a frequency range, The frequency can be various waveforms, including sine, square, triangle, saw tooth, staircase or any other wave shape. The driving frequencies are preferably in the range of about 10 KHz to 300 KHz.

A tube 28 is attached to the housing 12 and provides a passage for the signal cable 26 and also allows that housing to be rotated to different orientations. The housing enclosure 12 is sealed to prevent liquid from entering. The housing 12 is preferably proportioned so that it will float or attached to a separate float. The transducer 14 should be welded or bonded or otherwise fastened to the housing 12 at a node point of lowest longitudinal amplitude of the transducer to minimize transmitting energy onto the housing, in order to transmit maximum ultrasonic energy in the direction of the transducer axis to the transmitting head 20 and to the surrounding liquid.

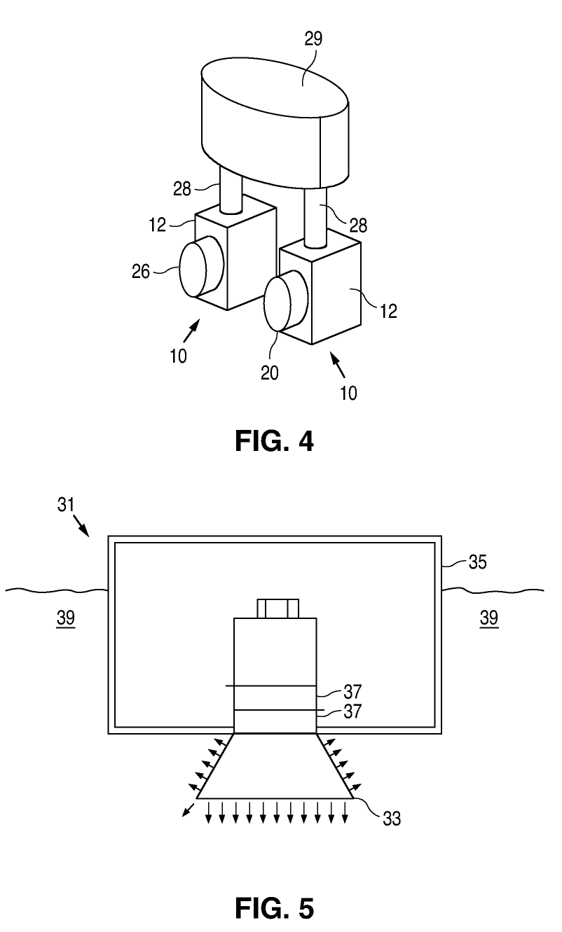

FIG. 4 shows two ultrasonic devices 10 both attached to and suspended below a float 29. Each device 10 has a transmitting head 20, a waterproof housing 12, and a tube 28 connecting the device to the float 29. The transmitting heads 20 are shown oriented in the same direction, but they can be oriented in any direction by rotating them around the tube 28. The ultrasonic generator 24 can be located inside the float 29 and powered by solar energy, or the ultrasonic generator can be placed remotely and connected to the ultrasonic devices with a cable.

FIG. 5 shows another embodiment of an ultrasonic device 31 with a different shaped transmitting head 33 and mounted inside a sealed housing 35. The PZTs 37 are radial mode, which expand and contract primarily in a radial direction. The radial ultrasonic vibrations of the PZTs 37 are conveyed to the transmitting head 33, which is located in the liquid 39 to be processed. Since there is no structure between the transmitting head and the liquid, the radial mode ultrasonic vibrations are transmitted very efficiently from the transducer to the liquid. This is in contrast to more conventional ultrasonic apparatus where the entire transducer structure is located on one side of a wall or plate, and all vibrations have to travel from the head mass and through the wall or plate to the liquid. The present invention significantly increases the surface area of the transmitting structure as compared to an intervening wall or plate. The present invention thus significantly improves the transmission of radial ultrasonic energy into the liquid.

FIG. 6 shows an embodiment of the present invention with multiple transducers 30, 32 of the same dimensions driven by a single sweep frequency generator 34. The housing enclosure 36 can be in any shape. The transmitting heads 38 and 40 protrude outside the housing 36. The sweep frequency waveform can be sine, square, triangle, saw tooth, staircase or any other wave shape depending on the application. The generator 34 preferably has amplitude modulation and the amplitude control.

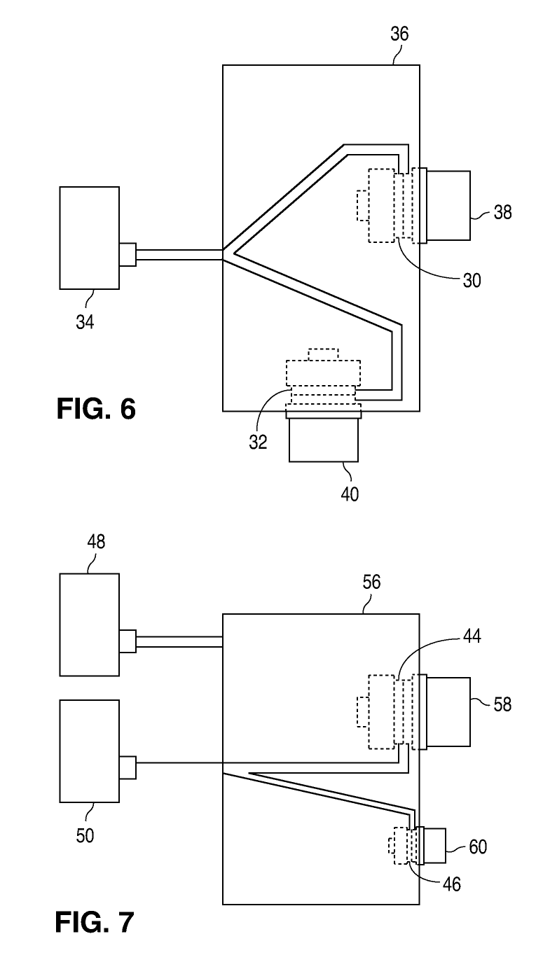

FIG. 7 shows an embodiment of the present invention with multiple transducers 44, 46 of different dimensions simultaneously driven by separate sweep-frequency generators 48, 50 through separate signal cables 52, 54. The smaller transducer 46 is driven at a higher frequency because it has a higher resonance frequency than the larger transducer 44. The housing enclosure 56 can be in any shape and the transducers can be mounting on the same (as shown) or different surfaces. Each transducer 48, 50 has a transmitting head 58, 60 that protrudes outside the housing 56. Preferably, each generator 48, 50 independently sweeps the frequency of its driving signal in various waveforms, such as sine, square, triangle, saw tooth, staircase or any other wave shape, and also preferably has amplitude modulation and amplitude control.

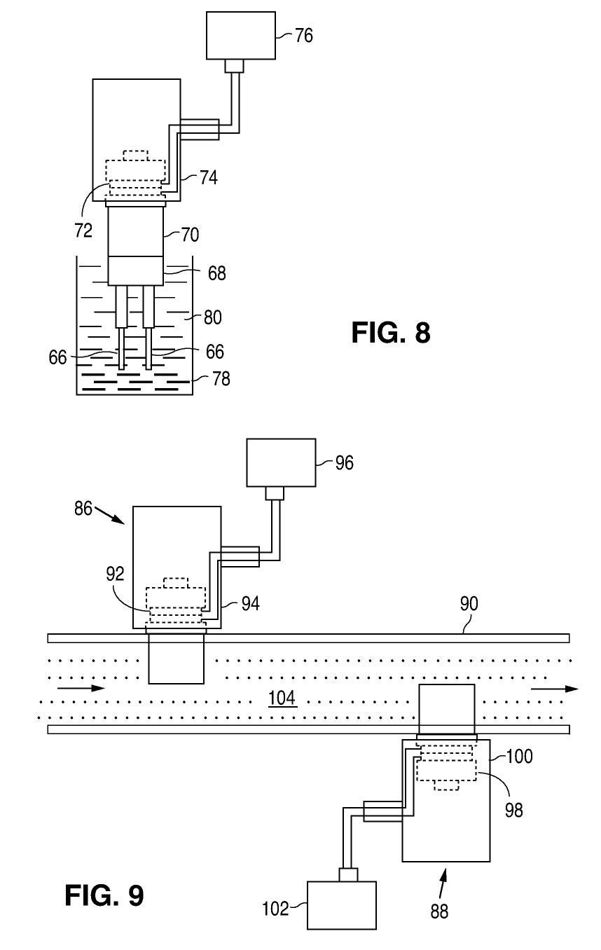

FIG. 8 shows an embodiment of the present invention for liquid processing with multiple probes 66 connected to a coupler 68 that is attached to the transmitting head 70 of an ultrasonic transducer 72 mounted in a housing 74 and driven by a frequency-sweeping generator 76. The probes 66 are inserted into a container or tank 78 that contains a liquid 80 to be processed. Each probe 66 continuously changes its peaks and nodes to accelerate the liquid processing by shearing proteins and disrupting cells.

FIG. 9 shows an embodiment of the present invention with two transmitting units 86 and 88 attached to a pipe line 90. Transmitting unit 86 has a lower frequency ultrasonic transducer 92 enclosed in a housing 94 and powered by a sweeping generator 96. Transmitting unit 88 has a higher frequency ultrasonic transducer 98 enclosed in a housing 100 and powered by another sweeping generator 102. The pipe line 90 can be, for example, a waste-water processing system line that carries a liquid 104 to be processed past the transmitting units. The lower frequency transducer 92 is used to break down large particles and the higher frequency transducer 98 is used to break smaller particles. One or more transducers of each type 86, 88 are connected to the pipe line 90.

The present invention is characterized in that the ultrasonic transducer used has its head mass (transmitting head) located outside the housing enclosure while the PZTs and tail mass are located inside the housing enclosure. Nothing separates the vibrating head mass from the liquid, which maximizes efficient transfer of ultrasonic energy to the liquid. The exposed surface area is increased, also contributing to the efficiency. Also, immersion of the transmitting unit in the liquid helps to cool the unit. Plus, by sweeping the driving frequencies, the liquid is subjected to a wide range of ultrasonic energy, increasing the likelihood that algae and other contaminants will break down. Multiple transmitting units can be driven simultaneously to increase the ultrasonic energy supplied to the liquid. The process of the present invention can prevent biological encroachments in fresh and ocean water, and can be used to process contaminated water, swimming pools, runoff from car washing, etc. Blood, urine or other human and animal fluids can be decontaminated. More generally, the ultrasonic device of the present invention can be used in any ultrasonic process involving supplying ultrasonic energy to liquids.

From the above description, it will be apparent that the invention disclosed herein provides a novel and advantageous ultrasonic apparatus, and related processes. The foregoing discussion discloses and describes merely exemplary methods and embodiments of the present invention. As will be understood by those familiar with the art, the invention may be embodied in various other forms without departing from the spirit or essential characteristics thereof. Accordingly, the disclosure of the present invention is intended to be illustrative, but not limiting, of the scope of the invention, which is set forth in the following claims.

1. A processing apparatus comprising:
an ultrasonic transducer having a transmitting head, one or more piezoelectric elements, and a tail mass;
a housing to which the transducer is attached with the transmitting head positioned outside the housing and the piezoelectric elements and tail mass positioned inside the housing.

2. A processing apparatus as recited in claim 1, further comprising an ultrasonic generator that supplies a variable frequency driving signal to the piezoelectric elements of the transducer.

3. A processing apparatus as recited in claim 1, wherein the housing is sealed and configured so that it floats on a liquid.

4. A processing apparatus as recited in claim 1, further comprising two probes affixed to and extending outwardly of a distal end of the transmitting head.

5. A processing apparatus as recited in claim 1, further comprising a second ultrasonic transducer having a transmitting head, one or more piezoelectric elements, and a tail mass, wherein the transmitting head of the second transducer is positioned outside the housing and the piezoelectric elements and tail mass of the second transducer are positioned inside the housing.

6. A processing apparatus as recited in claim 5, further comprising an ultrasonic generator that supplies a variable frequency driving signal to the piezoelectric elements of the two transducers.

7. A processing apparatus as recited in claim 5, further comprising a first ultrasonic generator that supplies a variable frequency driving signal to the piezoelectric elements of one transducer, and a second ultrasonic generator that supplies a variable frequency driving signal to the piezoelectric elements of the other transducer.

8. A processing system for processing liquids, comprising:
two or more ultrasonic transmitting units, each transmitting unit having an ultrasonic transducer with a transmitting head, one or more piezoelectric elements, and a tail mass and further having a housing to which the transducer is attached with the transmitting head positioned outside the housing and the piezoelectric elements and tail mass positioned inside the housing;
wherein the transmitting units are positioned with the transmitting heads in contact with a liquid to be processed; and;
an ultrasonic generator that supplies a variable frequency driving signal to the piezoelectric elements of the transducers.

9. A process for controlling algae, the process comprising the steps of:
providing two or more ultrasonic transmitting units, each transmitting unit having an ultrasonic transducer with a transmitting head positioned outside a housing and one or more piezoelectric elements and a tail mass positioned inside the housing;
positioning the transmitting heads in contact with a liquid to be processed, and;
supplying a variable frequency driving signal to the one or more piezoelectric elements of the transducers.

10. A process for supplying ultrasonic energy to a liquid, the process comprising the steps of:
providing two or more ultrasonic transmitting units, each transmitting unit having an ultrasonic transducer with a transmitting head positioned outside a housing and one or more piezoelectric elements and a tail mass positioned inside the housing;
positioning the transmitting heads in contact with a liquid to be processed, and;
supplying a variable frequency driving signal to the one or more piezoelectric elements of the transducers.
